(19) United States
(12) Patent Application Publication
(10) Pub. No.: US 2017/0020026 A1
(43) Pub. Date: Jan. 19, 2017

(54) VAPOR CHAMBER STRUCTURE

(71) Applicant: Celsia Technologies Taiwan, Inc., Taoyuan County (TW)

(72) Inventors: George A. Meyer, IV, Morgan Hill, CA (US); Hsin-Hua WEN, Taoyuan County (TW); Ming-Kuei HSIEH, Taoyuan County (TW); Chieh-Ping CHEN, Taoyuan County (TW); Yu-Ju LIU, Taoyuan County (TW); Mei-Yu CHEN, Taoyuan County (TW); Hui-Ju HO, Taoyuan County (TW)

(21) Appl. No.: 14/798,773

(22) Filed: Jul. 14, 2015

(51) Int. Cl. H05K 7/20

(52) U.S. Cl. CPC H05K 7/2029

(57) ABSTRACT

A vapor chamber structure includes an extruded aluminum case having a bottom plate and plural first separating units, an extruded aluminum cover combined with the extruded aluminum case correspondingly and having a top plate and plural second separating units, and a working fluid filled in an interior formed by the extruded aluminum case and the extruded aluminum cover. Each first separating unit includes plural first fins. A first groove is disposed between adjacent first fins. Each second separating unit includes plural second fins. A second groove is disposed between adjacent second fins. Each second separating unit is disposed between adjacent first separating units. The first grooves are individually interlaced with the adjacent second grooves. Thus, the heat exchange between the vaporized working fluid and the gas in adjacent grooves can be performed, which improves the efficiency of heat transfer.

### BACKGROUND OF THE INVENTION

Field of the Invention

The present invention relates to a vapor chamber structure and in particular to a vapor chamber structure used in a heat source of an electronic device.

Description of Prior Art

With the operating speed of the electronic device speeding up continuously, the generated heat amount becomes increasingly large. In order to solve the issue of high heat generation, the vapor chamber having high heat transfer properties is widely used in the industry. However, the heat transfer efficiency, manufacturing cost, and process complexity associated with such a vapor chamber still need improvement.

The traditional vapor chamber mainly comprises an upper case and a lower case. A lot of separation units which may be formed by metal powder sinter are first disposed in the interiors of the upper case and the lower case. Then, the upper case and the lower case are welded correspondingly and a working fluid is filled in the interiors of the upper case and the lower case. Finally, a degas process is performed and the whole manufacturing process is completed.

However, the traditional vapor chamber having high heat transfer properties has the following problems during operation. Numerous and complicated manufacturing steps result in a low production rate and high manufacturing cost. The grooves formed by the separation units are isolated except that the grooves formed at the front end and at the rear end communicate to each other, which causes poor mobility of the internal gas and thus the heat transfer rate can not be increased effectively.

### SUMMARY OF THE INVENTION

An objective of the present invention is to provide a vapor chamber structure in which the heat exchange between the vaporized working fluid and the gas in adjacent grooves can be performed to improve the efficiency of heat transfer.

In order to achieve the above objective, the present invention provides a vapor chamber structure, which comprises an extruded aluminum case, an extruded aluminum cover, and a working fluid. The extruded aluminum case has a bottom plate and a plurality of first separating units extending upward from the bottom plate. Each of the first separating units comprises a plurality of first fins. A first groove is disposed between any two adjacent first fins. The extruded aluminum cover is combined with the extruded aluminum case correspondingly. The extruded aluminum cover has a top plate and a plurality of second separating units extending downward from the top plate. Each of the second separating units comprises a plurality of second fins. A second groove is disposed between any two adjacent second fins. Each of the second separating units is disposed between any two adjacent first separating units. The first grooves of the first separating units are individually interlaced with the adjacent second grooves of the second separating units. The working fluid is filled in an interior formed by the extruded aluminum case and the extruded aluminum cover.

The present invention further has the following effects. The case and cover are made by extrusion, which achieves high production rate and low manufacturing cost, gains better combination strength between the fins and the bottom and top plates. For thinner plates, deformations of the case and the cover caused by vaporization and expansion of the internal liquid can be effectively prevented by means of the hook engagement of the first fins and the second fins. Also, the arrangement of the first fins and/or the second fins having a cross-sectional shape of “+” gives firm support and thus improves the strength of the whole structure.

### BRIEF DESCRIPTION OF DRAWING

FIG. 1 is an exploded view of a vapor chamber structure according to the first embodiment of the present invention;

FIG. 2 is a longitudinal cross-sectional assembled view of a vapor chamber structure according to the first embodiment of the present invention;

FIG. 3 is a transverse cross-sectional assembled view of a vapor chamber structure according to the first embodiment of the present invention;

FIG. 4 is an exploded view of a vapor chamber structure according to the second embodiment of the present invention;

FIG. 5 is a longitudinal cross-sectional assembled view of a vapor chamber structure according to the second embodiment of the present invention;

FIG. 6 is a longitudinal cross-sectional assembled view of a vapor chamber structure according to the third embodiment of the present invention; and FIG. 7 is a longitudinal cross-sectional assembled view of a vapor chamber structure according to the fourth embodiment of the present invention

### DETAILED DESCRIPTION OF THE INVENTION

The above objective and structural and functional features of the present invention will be described with reference to the preferred embodiments in the accompanying drawings. However, the accompanying figures are only for reference and explanation, but not to limit the scope of the present invention.

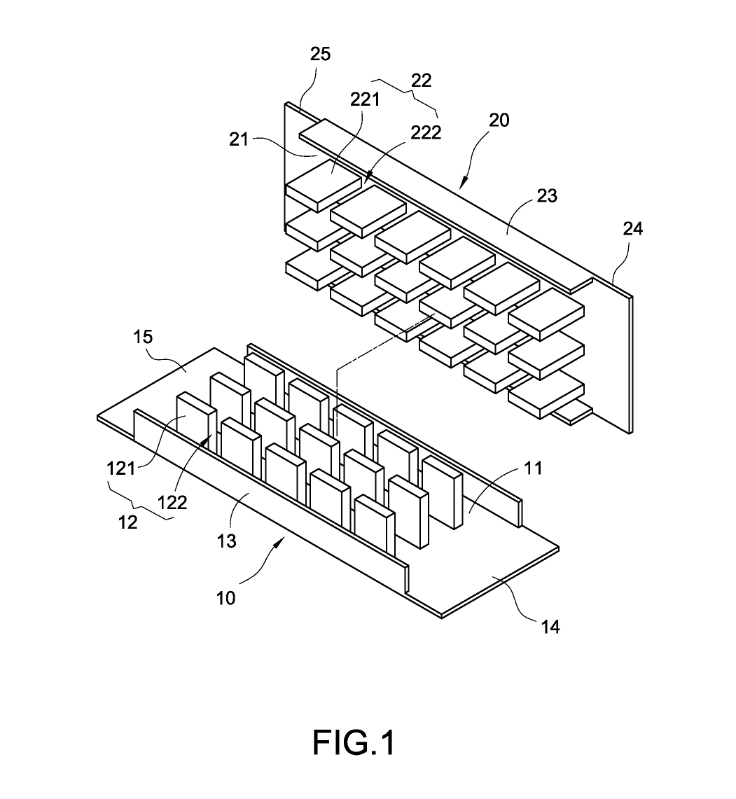

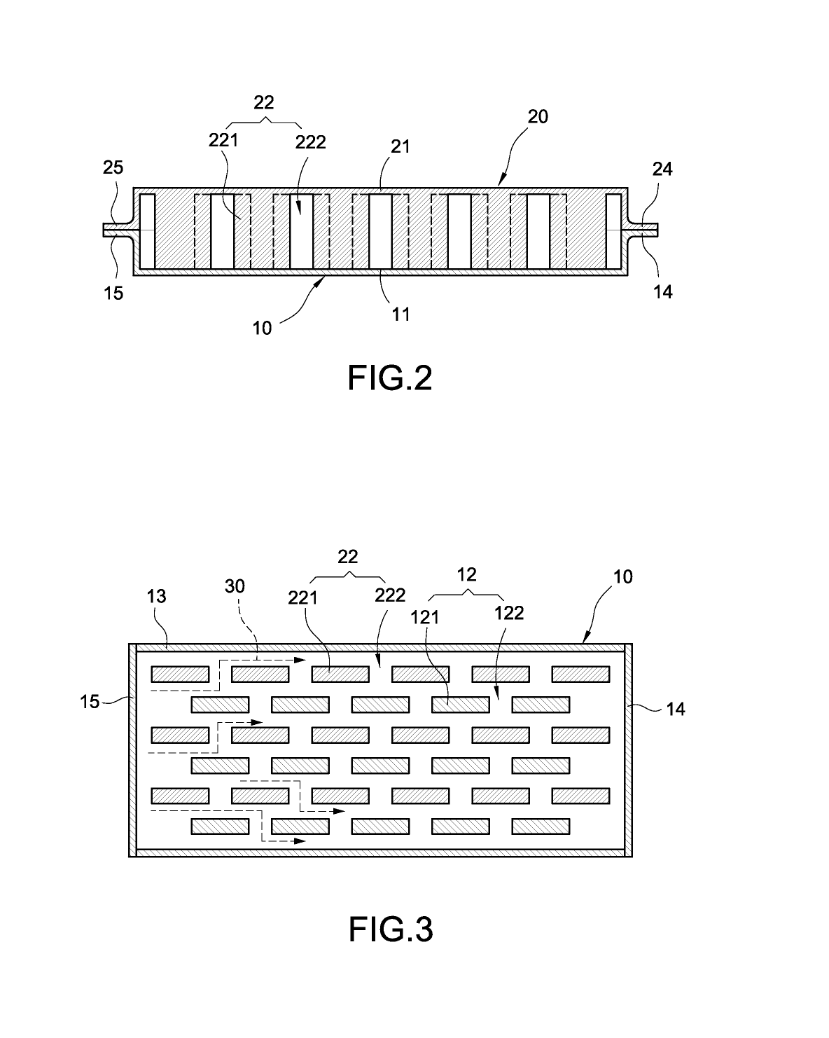

Please refer to FIGS. 1-3. The present invention provides a vapor chamber structure, which comprises an extruded aluminum case 10, an extruded aluminum cover 20, and a working fluid 30.

The extruded aluminum case 10 is made of aluminum or an alloy thereof, directly by extrusion. The extruded aluminum case 10 has a rectangular bottom plate 11 and a plurality of first separating units 12 extending upward from the bottom plate 11. The first separating units 12 are used for supporting and are formed integrated with the bottom plate 11. Each of the first separating units 12 comprises a plurality of first fins 121. A first groove 122 is disposed between any two adjacent first fins 121.

The extruded aluminum cover 20 is also made of aluminum or an alloy thereof, directly by extrusion. The extruded aluminum cover 20 has a rectangular top plate 21 and a plurality of second separating units 22 extending downward from the top plate 21. The second separating units 22 are used for supporting and are formed integrated with the top plate 21. Each of the second separating units 22 comprises a plurality of second fins 221. A second groove 222 is disposed between any two adjacent second fins 221. When the extruded aluminum cover 20 is combined with the extruded aluminum case 10 correspondingly, each of the second separating units 22 is disposed between any two adjacent first separating units 12; the first grooves 122 of the first separating units 12 are individually interlaced with the adjacent second grooves 222 of the second separating units 22.

Further, each of two sides of the bottom plate 11 extends to form a lower sidewall 13 which is parallel with the first separating units 12. Each of two sides of the top plate 21 extends to form an upper sidewall 23 which is parallel with the second separating units 22. The upper sidewall 23 and the lower sidewall 13 are connected correspondingly and sealed to each other by welding.

Moreover, the front side and the rear side of the bottom plate 11 form a front sealing plate 14 and a real sealing plate 15, respectively. The front side and the rear side of the top plate 21 form a front stacking plate 24 and a real stacking plate 25, respectively. The front sealing plate 14 is bent and sealed on a front side of the lower sidewall 13; the front stacking plate 24 is bent and sealed on a front end side of the upper sidewall 23 and is stacked with and sealed with the front sealing plate 14. The rear sealing plate 15 is bent and sealed on a rear end side of the lower sidewall 13; the rear stacking plate 25 is bent and sealed on a rear end side of the upper sidewall 23 and is stacked with and sealed with the rear sealing plate 15.

The working fluid 30 is filled and sealed in an interior formed by the extruded aluminum case 10 and the extruded aluminum cover 20. The working fluid 30 can be ammonia, sulfur dioxide, or non-haloalkane (e.g., methane).

Besides, the internal surfaces of the bottom plate 11 and the top plate 21, the surfaces of the first fins 121 and the second fins 221 may be coated with metal powder and form a wick structure (not shown) by a sinter process.

After the combination of the above-mentioned components is completed, the usage of the present invention is described below. The left side of the bottom plate 11 is attached evenly to the heat source of an electronic device (not shown). After the working fluid 30 is heated, it vaporizes from a liquid fluid to a gaseous fluid. The gaseous fluid flows from the grooves formed by the first fins 121 and the second fins 221 to a low-temperature place. When the gaseous fluid flows through the first grooves 122 and/or the second grooves 222, the heat transfer between the gaseous fluid and the gas in adjacent grooves can be performed to improve the efficiency of heat transfer of the vapor chamber.

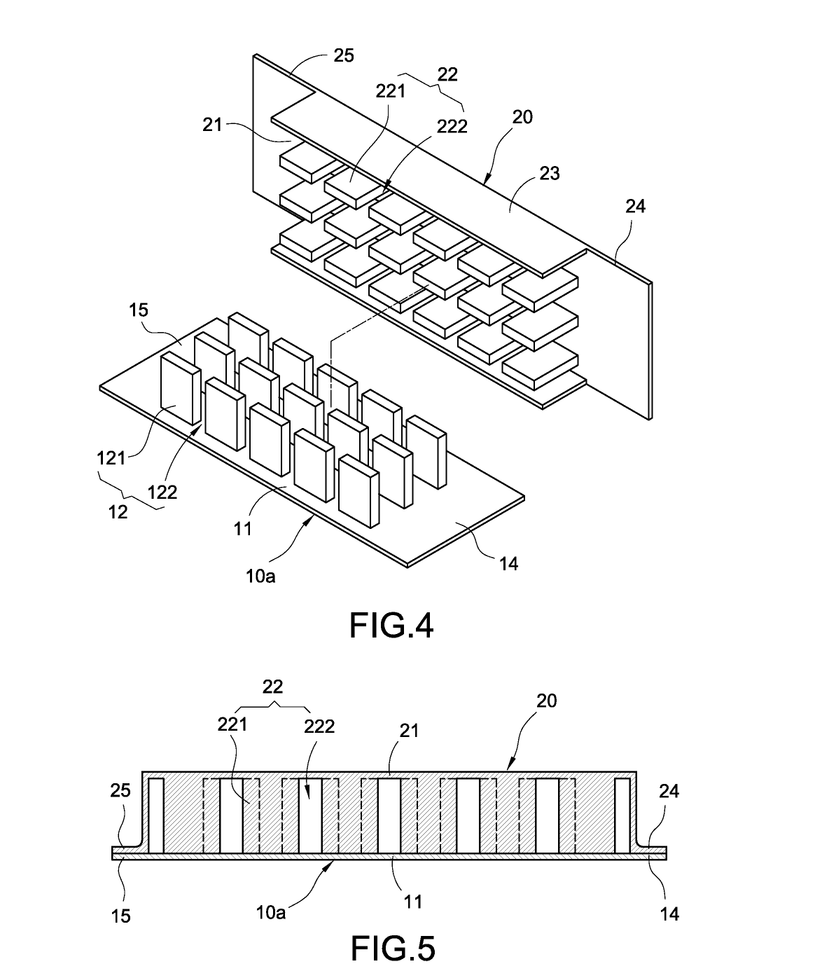

As shown in FIGS. 4 and 5, the vapor chamber structure of the present invention not only can be implemented as the previous (first) embodiment of the present invention, but also can be implemented as the current (second) embodiment. In the current embodiment, the extruded aluminum cover 20 is the same as that of the first embodiment. The extruded aluminum case 10a only comprises a bottom plate 11 and a plurality of first separating units 12 extending upward from the bottom plate 11. Each of the first separating units 12 comprises a plurality of first fins 121; a first groove 122 is disposed between any two adjacent first fins 121. During the combination, the upper end surface of each upper sidewall 23 of the top plate 21 is attached evenly to the bottom plate 11 and is sealed to each other by welding. Then, the front stacking plate 24 is bent and sealed on a front end side of the upper sidewall 23 and is stacked with and sealed with the bottom plate 11; the rear stacking plate 25 is bent and sealed on a rear end side of the upper sidewall 23 and is stacked with and sealed with the bottom plate 11.

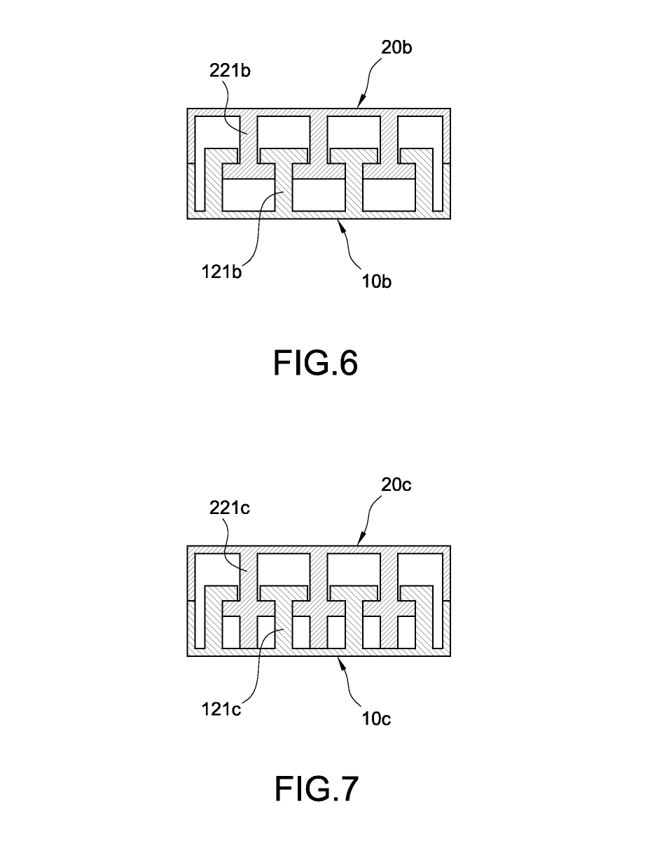

Please refer to FIG. 6. The extruded aluminum case 10b of the present invention extends to form a plurality of first fins 121b which have cross-sectional shapes of “T” or “L”, besides the “I” cross-sectional shape in the previous embodiments. Similarly, the extruded aluminum cover 20b extends to form a plurality of second fins 221b which have cross-sectional shapes of “T” or “L”, besides the “I” cross-sectional shape in the previous embodiments. By means of the hook engagement of the first fins 121b and the second fins 221b shown in FIG. 6, for thinner plates, deformations of the extruded aluminum case 10b and the extruded aluminum cover 20b caused by vaporization and expansion of the internal liquid can be effectively prevented.

Please further refer to FIG. 7. The extruded aluminum case 10c extends to form a plurality of first fins 121c having cross-sectional shapes of “T” or “L”. The extruded aluminum cover 20c extends to form a plurality of second fins 221c having cross-sectional shapes of “+”, which gives firm support and thus improves the strength of the whole structure.

In summary, the vapor chamber structure of the present invention can achieve the expected objective and overcome the disadvantages of the prior art. Also it is indeed novel, useful, and non-obvious to be patentable. Please examine the application carefully and grant it as a formal patent for protecting the rights of the inventor.

What is claimed is:

1. A vapor chamber structure, comprising:
an extruded aluminum case (10) having a bottom plate (11) and a plurality of first separating units (12) extending upward from the bottom plate (11), wherein each of the first separating units (12) comprises a plurality of first fins (121), wherein a first groove (122) is disposed between any two adjacent first fins (121);
an extruded aluminum cover (20) combined with the extruded aluminum case (10) correspondingly, wherein the extruded aluminum cover (20) has a top plate (21) and a plurality of second separating units (22) extending downward from the top plate (21), wherein each of the second separating units (22) comprises a plurality of second fins (221), wherein a second groove (222) is disposed between any two adjacent second fins (221), wherein the each of the second separating units (22) is disposed between any two adjacent first separating units (12), wherein the first grooves (122) of the first separating units (12) are individually interlaced with the adjacent second grooves (222) of the second separating units (22); and
a working fluid (30) filled in an interior formed by the extruded aluminum case (10) and the extruded aluminum cover (20).

2. The vapor chamber structure according to claim 1, wherein each of the first fins (121) has a cross-sectional shape of “I”, “T”, “L”, or “+”.

3. The vapor chamber structure according to claim 1, wherein each of the second fins (221) has a cross-sectional shape of “I”, “T”, “L”, or “+”.

4. The vapor chamber structure according to claim 1, wherein each of two sides of the bottom plate (11) extends to form a lower sidewall (13) parallel with the first separating units (12), wherein each of two sides of the top plate (21) extends to form an upper sidewall (23) parallel with the second separating units (22), wherein the upper sidewall (23) and the lower sidewall (13) are connected correspondingly and sealed to each other.

5. The vapor chamber structure according to claim 4, wherein one side of the bottom plate (11) extends to form a front sealing plate (14), wherein one side of the top plate (21) extends to form a front stacking plate (24), wherein the front sealing plate (14) is bent and sealed on a front end side of the lower sidewall (13), wherein the front stacking plate (24) is bent and sealed on a front end side of the upper sidewall (23) and is stacked with and sealed with the front sealing plate (14).

6. The vapor chamber structure according to claim 5, wherein the other side of the bottom plate (11) extends to form a rear sealing plate (15), wherein the other side of the top plate (21) extends to form a rear stacking plate (25), wherein the rear sealing plate (15) is bent and sealed on a rear end side of the lower sidewall (13), wherein the rear stacking plate (25) is bent and sealed on a rear end side of the upper sidewall (23) and is stacked with and sealed with the rear sealing plate (15).

7. The vapor chamber structure according to claim 1, wherein each of two sides of the top plate (21) extends to form an upper sidewall (23) parallel with the second separating units (22), wherein the upper sidewall (23) and the bottom plate (11) are connected correspondingly and sealed to each other.

8. The vapor chamber structure according to claim 7, wherein one side of the top plate (21) extends to form a front stacking plate (24) which is bent and sealed on a front end side of the upper sidewall (23) and is stacked with and sealed with the bottom plate (11).

9. The vapor chamber structure according to claim 8, wherein the other side of the top plate (21) extends to form a rear stacking plate (25) which is bent and sealed on a rear end side of the upper sidewall (23) and is stacked with and sealed with the bottom plate (11).

10. The vapor chamber structure according to claim 1, wherein the working fluid (30) is ammonia, sulfur dioxide, or non-haloalkane
